(19) United States
(12) Patent Application Publication
(10) Pub. No.: US 2014/0225263 A1
(43) Pub. Date: Aug. 14, 2014

(54) SEMICONDUCTOR DEVICE AND METHOD FOR MANUFACTURING SEMICONDUCTOR DEVICE

(71) Applicants: Takenao Nemoto, Sendai City (JP); Akinobu Teramoto, Sendai-shi (JP); Xun Gu, Sendai City (JP)

(72) Inventors: Takenao Nemoto, Sendai City (JP); Akinobu Teramoto, Sendai-shi (JP); Xun Gu, Sendai City (JP)

(73) Assignees: TOHOKU UNIVERSITY, Sendai-shi, Miyagi (JP); TOKYO ELECTRON LIMITED, Tokyo (JP)

(21) Appl. No.: 14/343,467

(22) PCT Filed: Sep. 6, 2012
(86) PCT No.: PCT/JP2012/072691

§ 371 Date: Apr. 17, 2014

(30) Foreign Application Priority Data
Sep. 7, 2011 (JP) 2011-195150

(51) Int. Cl. H01L 23/532; H01L 21/768

(52) U.S. Cl. CPC H01L 23/53238; H01L 21/76846
USPC 257/751; 438/653

(57) ABSTRACT

During the production of a semiconductor device having a Cu wiring line of a damascene structure, diffusion of fluorine from a CF film that serves as an interlayer insulating film is prevented in cases where a heat treatment is carried out, thereby suppressing increase in the leakage current. A semiconductor device of the present invention having a damascene wiring structure is provided with: an interlayer insulating film (2) that is formed of, for example, a fluorine-added carbon film; and a copper wiring line (4) that is embedded in the interlayer insulating film. A barrier metal layer (6) close to the copper wiring line and a fluorine barrier film (5) close to the interlayer insulating film are formed between the interlayer insulating film and the copper wiring line.

### TECHNICAL FIELD

The present disclosure relates to a semiconductor device and a method for manufacturing the semiconductor device.

### BACKGROUND

As for a wiring for a semiconductor device, a Cu wiring has recently been used so as to achieve a low resistance and a high reliability. It is difficult to form a Cu wiring through dry etching. Thus, such a Cu wiring has a damascene wiring structure in which multi-layered wirings are formed. The damascene wiring structure is manufactured by depositing a Cu film in a groove of a wiring pattern formed on an interlayer insulating film, and then removing the Cu film deposited at an area other than the groove by a chemical mechanical polishing (“CMP”) method.

When a fine Cu wiring is formed, an insulation property within an interlayer insulating film may deteriorate due to the diffusion of Cu which is an easily diffused element. Accordingly, it is known that a barrier metal is interposed between the Cu wiring and the interlayer insulating film so as to suppress Cu from being diffused. As for the barrier metal, for example, Ta (tantalum) or a compound thereof such as TaN (tantalum nitride), is used.

Meanwhile, it is known that, as for an interlayer insulating film, a CF film (a fluorine-added carbon film) which is a compound of carbon (C) and fluorine (F) is used. When a Cu wiring of a semiconductor device is formed, a heat loading process such as, for example, an annealing process, is performed. In such a heat treatment process, for example, the semiconductor device is heated at a temperature ranging from about 250° C. to 350° C., and fluorine is diffused into a barrier metal from the CF film which is an interlayer insulating film, during the heat treatment. Then, when the barrier metal is, for example, Ta (or a compound thereof), TaF₅ (tantalum fluoride) is generated within the barrier metal.

TaF₅ has a very high vapor pressure. Thus, TaF₅ is evaporated during the above described heat treatment process such that the density of Ta in the barrier metal may be reduced. Thus, a role of the barrier metal, that is, an effect of suppressing Cu from being diffused, may deteriorate. Accordingly, a leakage current may be increased in the semiconductor device, thereby causing a device defect. Further, the adhesion between the interlayer insulating film which is the CF film and the barrier metal may be reduced.

Therefore, for example, Patent Document 1 discloses a semiconductor device of which a barrier metal includes a first film, for example, a Ti (titanium) film that suppresses fluorine from being diffused from a CF film, and a second film, for example, a Ta (tantalum) film that suppresses Cu from being diffused from a Cu wiring. Further, for example, Patent Document 2 discloses a damascene-type Cu wiring structure including a barrier layer made of, for example, TaN or TiN, and an adhesive layer made of, for example, Ta or Ti.

### PRIOR ART DOCUMENT

### Patent Document

Patent Document 1: Japanese Patent Laid-Open Publication No. 2008-4841
Patent Document 2: US Patent Application Publication No. 2006/0113675

### DISCLOSURE OF THE INVENTION

### Problems to be Solved

As a result of intensive research, the inventors have found that, when a heat treatment process such as, for example, an annealing process, is performed in a state where the Ti film or the TiN film used in Patent Documents 1 and 2 is in contact with an interlayer insulating film which is a CF film during the manufacturing of a semiconductor device, fluorine is diffused into the Ti film or the TiN film from the CF film. As a result, TiF₄ (titanium fluoride) is generated within the Ti film or the TiN film and a leakage current of the semiconductor device is increased, thereby causing a device defect.

The present disclosure has been made in consideration of these problems, and an object of the present disclosure is to provide a semiconductor device and a manufacturing method of the semiconductor device in which, when a heat treatment process is performed during the manufacturing of a semiconductor device having a Cu wiring with a damascene structure, diffusion of fluorine from a CF film as an interlayer insulating film and an increase of a leakage current may be suppressed.

### Means to Solve the Problems

In order to achieve the above described abject, according to an aspect of the present disclosure, there is provided a semiconductor device having a damascene wiring structure. The semiconductor device includes: an interlayer insulating film including a fluorine-added carbon film, and a copper wiring filled in the interlayer insulating film, wherein, between the interlayer insulating film and the copper wiring, a barrier metal layer and a fluorine barrier film are formed close to the copper wiring and the interlayer insulating film, respectively.

In the semiconductor device, the fluorine bather film may be an aCSiO (amorphous carbon silicon oxide) film, an aCSiON (amorphous carbon silicon oxide nitride) film, or a SiCN (silicon carbon nitride) film). The fluorine barrier film may have a thickness of 5 nm or more.

According to another aspect of the present disclosure, there is provided a method for manufacturing a semiconductor device having a damascene wiring structure. The method includes: forming an interlayer insulating film including a fluorine-added carbon film, forming a wiring groove on the interlayer insulating film, forming a fluorine barrier film in the wiring groove, forming a barrier metal layer on a surface of the fluorine barrier film, and forming a copper wiring in the wiring groove after the fluorine barrier film and the barrier metal layer are formed.

In the method for manufacturing the semiconductor device, the fluorine barrier film may be an aCSiO (amorphous carbon silicon oxide) film, an aCSiON (amorphous carbon silicon oxide nitride) film or a SiCN (silicon carbon nitride) film). The fluorine barrier film may have a thickness of 5 nm or more.

### Effect of the Invention

According to the present disclosure, there is provided a semiconductor device and a manufacturing method of the semiconductor device in which, when a heat treatment process was performed during the manufacturing of a semiconductor device having a Cu wiring with a damascene structure, diffusion of fluorine from a CF film as an interlayer insulating film and an increase of a leakage current may be suppressed.

### BRIEF DESCRIPTION OF THE DRAWINGS

FIG. 1 is a cross-sectional view of a substrate for describing a manufacturing process of a semiconductor device according to a first exemplary embodiment of the present disclosure in which a wiring groove is formed on the surface of an interlayer insulating film.

FIG. 2 is a cross-sectional view of the substrate for describing the manufacturing process of the semiconductor device subsequently to FIG. 1 in which a fluorine barrier film and a barrier metal film are successively formed on the interlayer insulating film.

FIG. 3 is a cross-sectional view of the substrate for describing the manufacturing process of the semiconductor device subsequently to FIG. 2 in which a Cu conductive layer is formed on the entire surface of the substrate.

FIG. 4 is a cross-sectional view of the substrate for describing the manufacturing process of the semiconductor device subsequently to FIG. 3 in which the Cu conductive layer, the barrier metal film and the fluorine barrier film 5 are removed from the top of the interlayer insulating film.

FIG. 5 is a cross-sectional view of the substrate for describing the manufacturing process of the semiconductor device subsequently to FIG. 4 in which a sealing film is formed on the entire surface of the substrate.

FIG. 6 is a cross-sectional view of a substrate for describing a manufacturing process of a semiconductor device according to a second exemplary embodiment of the present disclosure in which an interlayer insulating film is formed on the top surface of a Cu wiring structure of a first layer.

FIG. 7 is a cross-sectional view of the substrate for describing the manufacturing process of the semiconductor device subsequently to FIG. 6 in which a wiring groove is formed on the surface of the interlayer insulating film of a second layer.

FIG. 8 is a cross-sectional view of the substrate for describing the manufacturing process of the semiconductor device subsequently to FIG. 7 in which, in the second layer, a fluorine barrier film is formed on the interlayer insulating film.

FIG. 9 is a cross-sectional view of the substrate for describing the manufacturing process of the semiconductor device subsequently to FIG. 8 in which, in the second layer, the fluorine barrier film is removed from the bottom surface of the wiring groove.

FIG. 10 is a cross-sectional view of the substrate for describing the manufacturing process of the semiconductor device subsequently to FIG. 9 in which, in the second layer, a barrier metal film is formed.

FIG. 11 is a cross-sectional view of the substrate for describing the manufacturing process of the semiconductor device subsequently to FIG. 10 in which in the second layer, a Cu conductive layer is formed on the entire surface of the substrate.

FIG. 12 is a cross-sectional view of the substrate for describing the manufacturing process of the semiconductor device subsequently to FIG. 11 in which, in the second layer, the Cu conductive layer, the barrier metal film and the fluorine barrier film are removed from the top of the interlayer insulating film.

FIG. 13 is a cross-sectional view of the substrate for describing the manufacturing process of the semiconductor device subsequently to FIG. 12 in which, in the second layer, a sealing film is formed on the entire surface of the substrate.

FIG. 14 is a graph illustrating a change of a leakage current when an annealing process was performed in which the change of the leakage current was measured on a semiconductor device manufactured by using a CF film as an interlayer insulating film, and a semiconductor device manufactured by using BD as an interlayer insulating film.

FIG. 15 is a graph illustrating a change of a leakage current when an annealing process was performed in which the change of the leakage current was measured on a semiconductor device manufactured without forming a fluorine barrier film, a semiconductor device manufactured by forming a fluorine barrier film of 10 nm thickness between an interlayer insulating film and a barrier metal film, and a semiconductor device manufactured by forming a fluorine barrier film of 15 nm thickness between an interlayer insulating film and a barrier metal film.

### DETAILED DESCRIPTION TO EXECUTE THE INVENTION

Hereinafter, exemplary embodiments of the present disclosure will be described with reference to drawings. In the present specification and drawings, components having substantially the same functional structures are given the same reference numerals, and a repetitive description thereof will be omitted.

### First Exemplary Embodiment

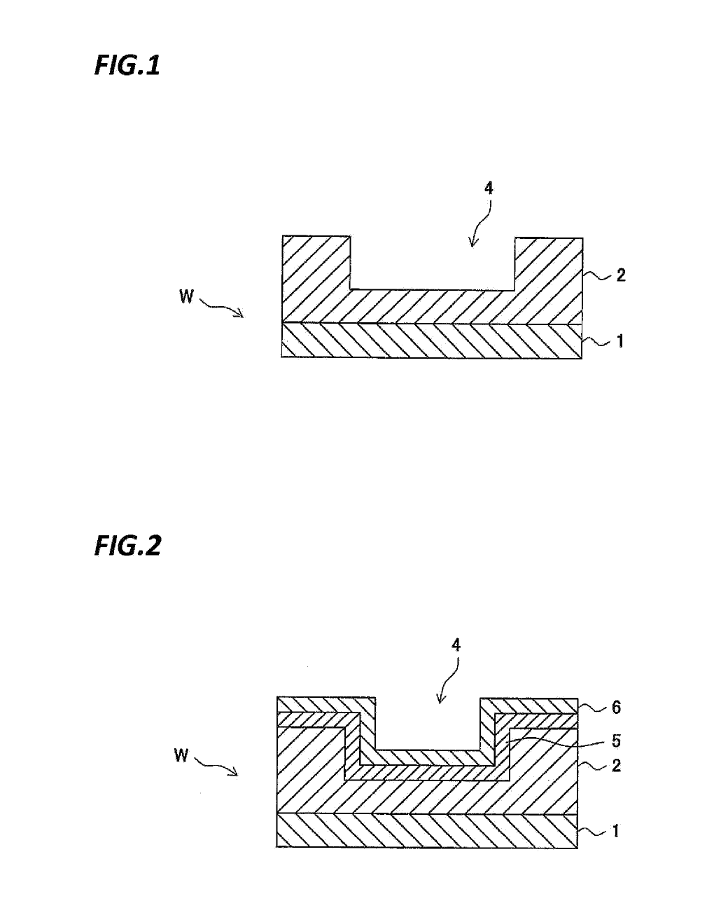

First, a manufacturing process of manufacturing a Cu wiring structure according to a first exemplary embodiment of the present disclosure will be described. FIGS. 1 to 5 are cross-sectional views of a substrate for describing a manufacturing process of manufacturing a Cu wiring structure according to the present exemplary embodiment. That is, FIGS. 1 to 5 illustrate a process of forming a Cu wiring on a top surface of a substrate main body 1 in a substrate W made of, for example, Si.

First, as illustrated in FIG. 1, an interlayer insulating film 2 which is a CF film (fluorine-added carbon film) is formed on the substrate main body 1 by a deposition method using plasma generated by, for example, a radial line slot antenna. Subsequently, a wiring groove 4 is formed on the surface of the interlayer insulating film 2 by photolithography and reactive ion etching (RIE).

Then, as illustrated in FIG. 2, a fluorine barrier film 5 and a barrier metal (“BM”) film 6 are successively formed on the interlayer insulating film 2 to cover the inner surface of the wiring groove 4. The fluorine barrier film 5 is a silicon-based insulating film which is formed by a deposition method using plasma generated by, for example, a radial line slot antenna, and the fluorine barrier film 5 may be an aCSiO (amorphous carbon silicon oxide) film, an aCSiON (amorphous carbon silicon oxide nitride) film or a SiCN (silicon carbon nitride) film. When the fluorine barrier film 5 is formed, for example, under the condition of a temperature of 350° C. or less, a microwave power of 2.5 kW, a pressure of 50 mTorr, TMS (trimethylsilane), O₂ (oxygen) and C₄H₆ (butyne) are introduced into a plasma deposition apparatus provided with a radial line slot antenna to perform film formation. Since the silicon-based insulating film is excellent in terms of adhesion, the fluorine barrier film 5 is formed on the interlayer insulating film 2 while maintaining its high adhesion.

The BM film 6 is formed on the entire surface of the fluorine bather film 5 by sputtering, for example, a Ti film or a Ta film. The BM film 6 may be a monolayer film such as, for example, a Ti film, a Ti compound film, or a Ti alloy film, or a multilayered film of two or more of these films, or may be a monolayer film such as, for example, a Ta film, a Ta compound film, a Ta alloy film or a multilayered film of two or more of these films.

As illustrated in FIG. 2, the thickness of the fluorine barrier film 5 to be formed is preferably 5 nm or more. This is because when the thickness of the fluorine barrier film 5 is less than 5 nm, the barrier property of fluorine (F) may not be sufficiently maintained. That is, considering the diffusion coefficient of fluorine (F), fluorine (F) may easily penetrate the fluorine barrier film 5 with a thickness of less than 5 nm Thus, it is desirable that the fluorine barrier film 5 has a thickness of at least 5 nm. This is supported by a test result indicating that the fluorine barrier film 5 with a thickness of 5 nm or more is good in diffusion blocking of fluorine (F) when the fluorine barrier film 5 is left, for example, in a fluorine gas atmosphere at 350° C. for 24 hours.

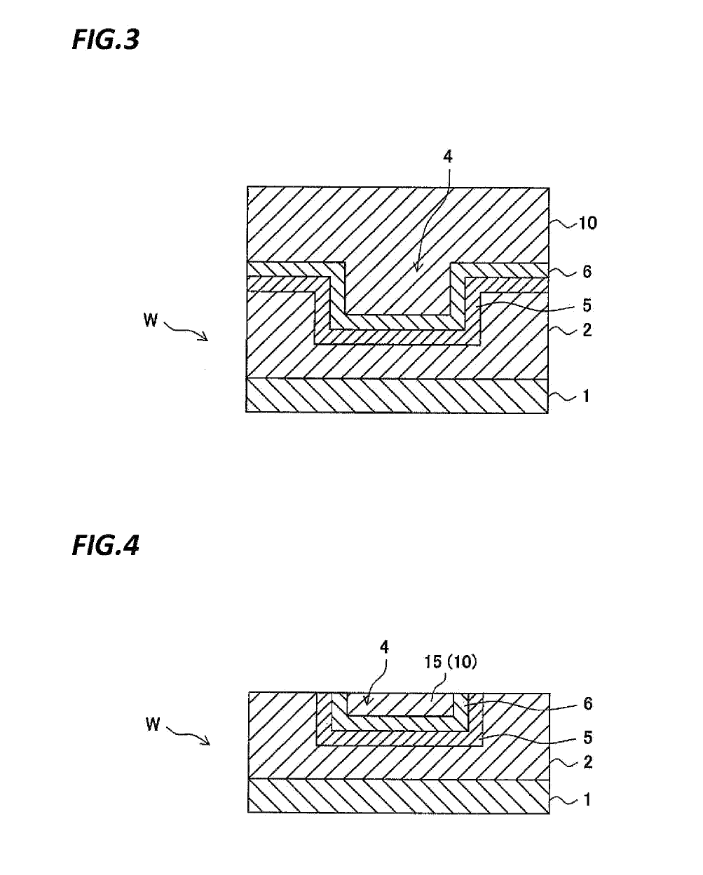

Then, as illustrated in FIG. 3, a Cu conductive layer 10 is formed on the entire surface of the substrate W to fill the wiring groove 4 from the top of the BM film 6. The Cu conductive layer 10 is not limited to pure Cu, but may be a Cu alloy. The Cu conductive layer 10 is formed by, for example, Cu alloy plating or sputtering.

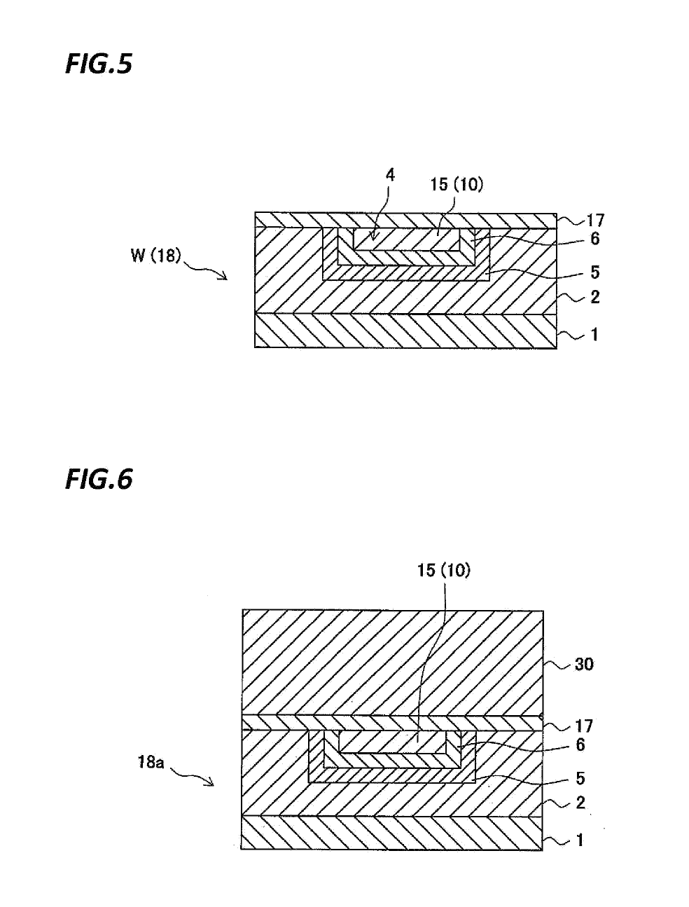

As illustrated in FIG. 4, from the top of the interlayer insulating film 2, the Cu conductive layer 10, the BM film 6, and the fluorine bather film 5 are removed by a CMP method while leaving the portions of the Cu conductive layer 10, the BM film 6 and the fluorine barrier film 5 within the wiring groove 4. In this manner, a Cu wiring 15 (the Cu conductive layer 10) is formed within the wiring groove 4 in a state where it is surrounded by the fluorine barrier film 5 and the BM film 6 which are sequentially formed from the interlayer insulating film 2 side. Then, as illustrated in FIG. 5, a sealing film 17 is formed to seal the top surface (upper side) of the interlayer insulating film 2 and the Cu wiring 15, thereby manufacturing a Cu wiring structure 18 having a damascene wiring structure. The sealing film 17 is, for example, a SiCN film or a SiCO film.

As the fluorine barrier film 5, in manufacturing the Cu wiring structure 18, the CSiO (amorphous carbon silicon oxide) film, the aCSiON (amorphous carbon silicon oxide nitride) film and the SiCN (silicon carbon nitride) film were exemplified. However, when these silicon-based insulating films are formed, it is desirable to introduce oxygen (O) or nitrogen (N) in the second half of the film formation in order to ensure the adhesion in relation to the interlayer insulating film 2 which is a CF film. That is, as illustrated in FIG. 2, when for example, an aCSiO film is formed as the fluorine barrier film 5, an aCSi film is formed without introducing oxygen at the time of film formation in the vicinity of the interlayer insulating film 2 (in the first half of the film formation), and the aCSiO film is formed by introducing oxygen at the time of film formation in the vicinity of the BM film 6 (in the second half of the film formation), thereby forming the fluorine bather film 5 with high adhesion in relation to the interlayer insulating film 2 which is a CF film. Likewise, when an aCSiON film or a SiCN film is formed as the fluorine barrier film 5, oxygen or nitrogen is introduced in the second half of the film formation to form the fluorine barrier film 5 with high adhesion in relation to the interlayer insulating film 2.

In the manufacturing process of the Cu wiring structure described above with reference to FIGS. 1 to 5, in order to stabilize the crystal structure, an annealing process is generally performed by heating at a temperature ranging from 250° C. to 350° C. during the manufacturing process.

As for a bather metal layer (corresponding to the BM film 6) in the Cu wiring structure, for example, Ti or Ta (or a compound thereof) is used. In this case, due to the barrier metal layer made of a metal, Cu is suppressed from being diffused from the Cu conductive layer 10 to the interlayer insulating film 2. However, if the annealing process is performed in a state where the fluorine barrier film 5 is not formed between the interlayer insulating film 2 and the BM film 6, fluorine is diffused from the interlayer insulating film 2 which is a CF film to the barrier metal layer, thereby generating TiF₄ or TaF₅. This reduces the density of Ti or Ta in the barrier metal layer. That is, the inventors have found that in a manufacturing process of a conventional Cu wiring structure, a barrier metal layer may suffer from reduction of a barrier property that suppresses Cu from being diffused, and a leakage current may be increased in the Cu wiring structure. This finding will be described in detail in Examples to be described below.

In this regard, in the configuration according to the present exemplary embodiment, based on the above described finding, for example, as illustrated in FIGS. 2 to 5, the fluorine barrier film 5 which is a silicon-based insulating film is formed between the interlayer insulating film 2 and the BM film 6. Therefore, even when a heat loading process such as, for example, an annealing process, is performed on a wiring structure, it is possible to suppress fluorine from being diffused from the interlayer insulating film 2 which is a CF film, to the BM film 6. Accordingly, the damascene-type Cu wiring structure 18 in which an increase of leakage current is suppressed is manufactured, and thus, for example, occurrence of a device defect may be suppressed. As described above, the fluorine barrier film 5 according to the present exemplary embodiment is very effective in the barrier property of fluorine. This may be because, for example, carbon (C) is highly hydrophobic, thereby blocking fluorine (F). Further, this may be because, carbon (C) and fluorine (F) may be easily bonded to each other.

As described above, in the first exemplary embodiment of the present disclosure, an example of the present disclosure has been described. However, the present disclosure is not limited to the above described exemplary embodiment. It is apparent to a person ordinarily skilled in the art that various modifications and changes may be made within the scope of the spirit of claims and the modifications and changes naturally belong to the technical scope of the present disclosure.

For example, in the above described first exemplary embodiment, a single Cu wiring structure 18 is manufactured, but a damascene-type Cu wiring structure in a semiconductor device is generally configured as a so-called dual damascene structure in which Cu wirings overlap each other in a plurality of layers.

### Second Exemplary Embodiment

Therefore, descriptions will be made on a so-called double damascene wiring structure according to the second exemplary embodiment of the present disclosure, in which two Cu wiring structures are connected to each other through a via wiring to be formed in two overlapping layers.

FIGS. 6 to 13 are cross-sectional views of a substrate for describing a process of manufacturing a Cu wiring structure according to the present exemplary embodiment, in which Cu wiring structures 18a (a first layer) and 18b (a second layer) disposed in two layers are via-connected. In the second exemplary embodiment, descriptions will be made on a case where the Cu wiring structure 18 (that is, 18a herein) manufactured as described in the first exemplary embodiment is a first layer, and the Cu wiring structure 18b as a second layer is formed above the first layer as illustrated in the drawings.

First, as illustrated in FIG. 6, an interlayer insulating film 30 which is a CF film is formed by a deposition method using plasma excited by, for example, a radial line slot antenna, on the surface of the Cu wiring structure 18a (of the first layer) manufactured by the manufacturing method according to the first exemplary embodiment described above.

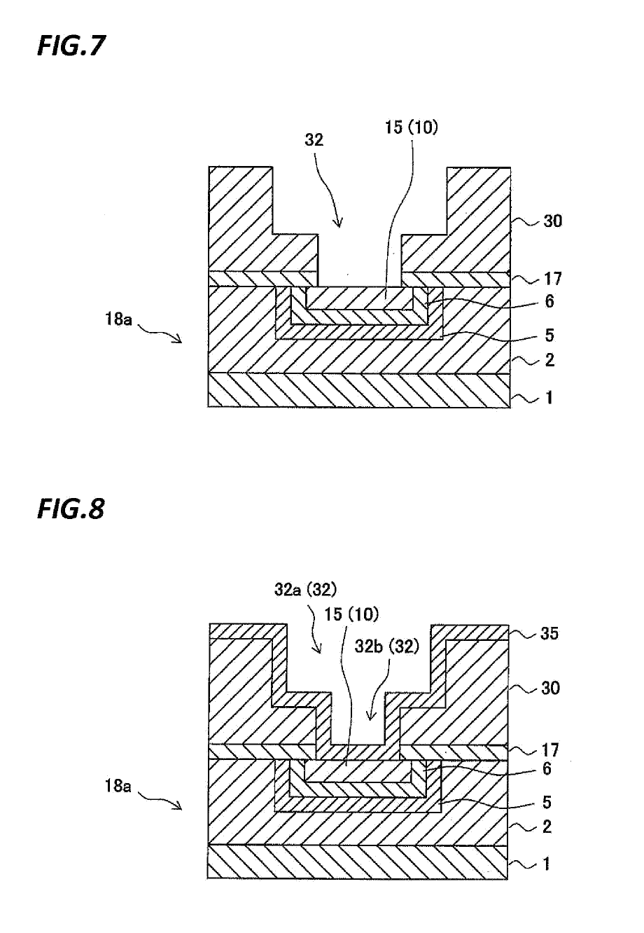

Sequentially, as illustrated in FIG. 7, a wiring groove 32 which includes a trench groove 32a of a damascene structure and a via hole 32b is formed on the surface of the interlayer insulating film 30 by photolithography and reactive ion etching (RIE). The wiring groove 32 is formed to penetrate the sealing film 17 formed on the top surface of the Cu wiring structure 18a of the first layer.

Next, as illustrated in FIG. 8, a fluorine barrier film 35 is formed to cover the inner surface of the wiring groove 32. As in the first exemplary embodiment, the fluorine barrier film 35 is a silicon-based insulating film which is formed by a deposition method using plasma excited by a radial line slot antenna, and examples of the fluorine barrier film 35 may include an aCSiO (amorphous carbon silicon oxide) film, an aCSiON (amorphous carbon silicon oxide nitride) film or a SiCN (silicon carbon nitride) film.

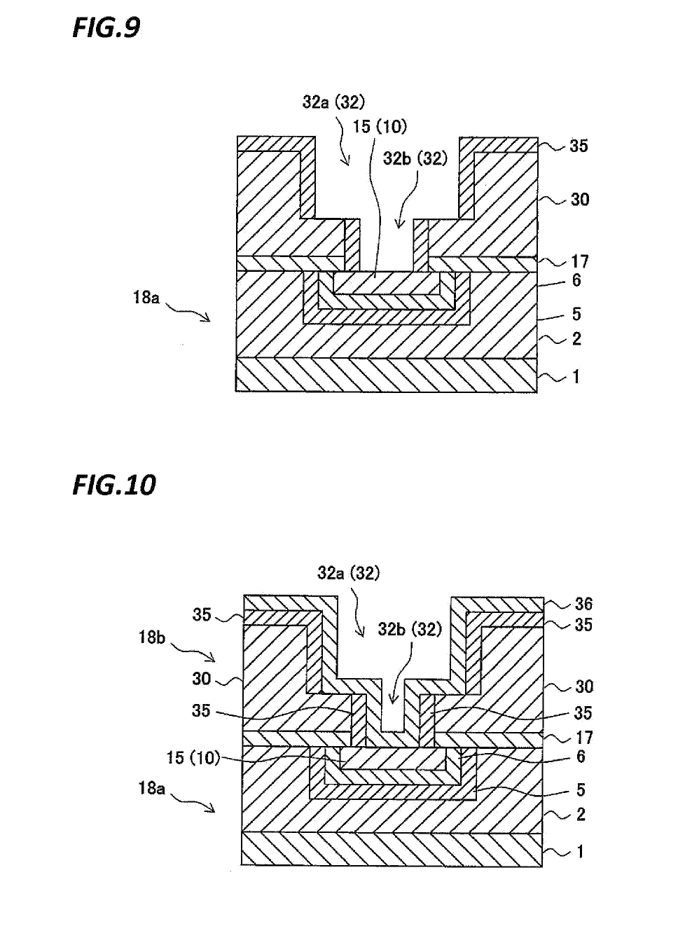

Next, as illustrated in FIG. 9, the fluorine barrier film 35 formed on the bottom surface of the wiring groove 32 is removed by punching. That is, in the wiring groove 32, the fluorine barrier film 35 formed on the bottom surface of the trench groove 32a and the bottom surface of the via hole 32b is removed and the fluorine barrier film 35 remains only on side surfaces (side walls) of the trench groove 32a and the via hole 32b.

FIG. 9 illustrates the state where the fluorine barrier film 35 is removed from the bottom portion of the via hole 32b. The removal of the fluorine barrier film 35 through punching is to remove the fluorine bather film 35 formed on the bottom surface of the via hole 32b.

As described above, the fluorine barrier film 35 is a silicon-based insulating film. Thus, if the Cu wiring structure 18b of the second layer is formed in a state where the fluorine barrier film 35 is formed on the bottom surface of the via hole 32b, the silicon-based insulating film is formed on the bottom portion (lower portion) of a via wiring that electrically connects the Cu wiring structure 18a of the first layer to the Cu wiring structure 18b of the second layer (that is, the Cu wiring formed within the via hole 32b). The Cu wiring of a finally manufactured double damascene structure has a configuration in which the Cu wiring structure 18a of the first layer and the Cu wiring 18b of the second layer are not electrically conductive to each other. Therefore, on the bottom surface of the via hole 32b, it is required to remove the fluorine barrier film 35.

Then, as illustrated in FIG. 10, a BM film 36 is formed to cover the inner surface of the wiring groove 32. The BM film 36 is formed on the entire surface of the fluorine barrier film 35 by sputtering, for example, a Ti film or a Ta film in the same manner as in the first exemplary embodiment. The BM film 36 may be a monolayer film such as, for example, a Ti film, a Ti compound film, or a Ti alloy film, or a multilayered film of two or more of these films, or may be a monolayer film such as, for example, a Ta film, a Ta compound film, a Ta alloy film or a multilayered film of two or more of these films.

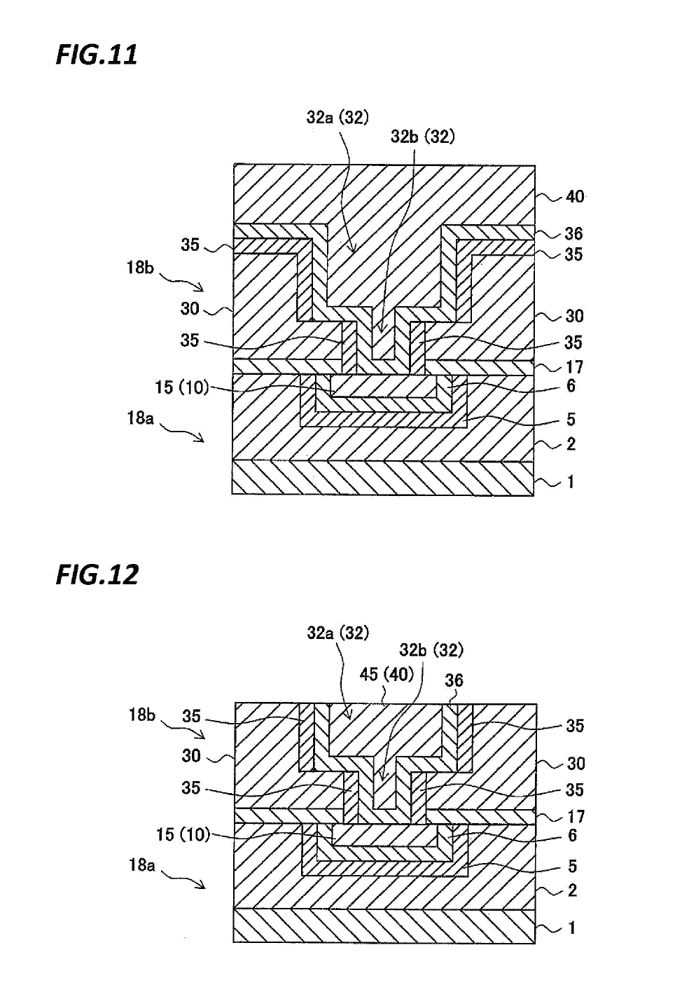

Subsequently, as illustrated in FIG. 11, a Cu conductive layer 40 is formed on the entire surface of the substrate to fill the wiring groove 32 from the top of the BM film 36. The Cu conductive layer 40 is not limited to pure Cu, but may be a Cu alloy. The Cu conductive layer 40 is formed by, for example, Cu alloy plating or sputtering.

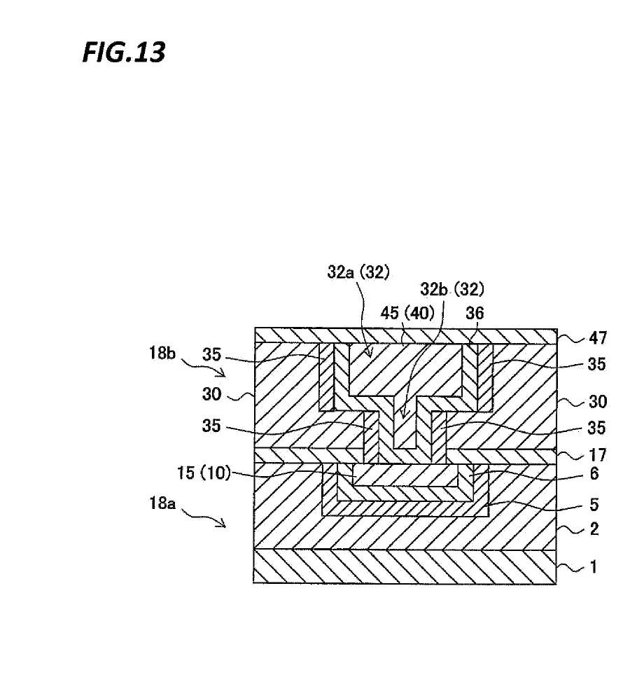

As illustrated in FIG. 12, from the top of the interlayer insulating film 30, the Cu conductive layer 40, the BM film 36 and the fluorine barrier film 35 are removed by a CMP method while leaving the portions of the Cu conductive layer 40, the BM film 36 and the fluorine barrier film 35 within the wiring groove 32. In this manner, a Cu wiring 45 (the Cu conductive layer 40) is formed within the wiring groove 32 in a state where it is surrounded by the fluorine barrier film 35 (a so-called side liner) at the side wall portion and the BM film 6 which are sequentially formed from the interlayer insulating film 30 side. As illustrated in FIG. 13, a sealing film 47 is formed to seal the top surface (upper side) of the interlayer insulating film 30 and the Cu wiring 45, thereby manufacturing a Cu wiring structure 48 having a so-called double damascene structure.

In the configuration of the Cu wiring structure 48 having a double damascene structure manufactured by the manufacturing process as described above with reference to FIGS. 6 to 13, the fluorine barrier film 5 which is a silicon-based insulating film is formed between the interlayer insulating film 2 and the BM film 6, and the fluorine barrier film 35 is further formed between the interlayer insulating film 30 and the BM film 36. Thus, even when a heating treatment such as, for example, an annealing process is performed on a wiring structure, it is possible to prevent fluorine from being diffused from the interlayer insulating films 2 and 30 which are CF films, to the BM films 6 and 36. That is, the double damascene-type Cu wiring structure 48 in which an increase of leakage current is suppressed is manufactured, and thus, for example, occurrence of a device defect may be suppressed.

The description of the first exemplary embodiment has been made on a case where the present disclosure is employed in a Cu wiring structure of a single layer structure, and the description of the second exemplary embodiment has been made on a case where the present disclosure is employed in a Cu wiring structure of a so-called double damascene structure (in two layers). However, it is natural that the present disclosure may be employed in a configuration in which Cu wirings overlap in a plurality of layers.

### EXAMPLES

It has been found that when a CF film is used as an interlayer insulating film in a manufacturing process of a conventional Cu wiring structure, a barrier metal layer may suffer from reduction of a barrier property that suppresses Cu from being diffused and a leakage current may be increased in the Cu wiring structure. This finding will be described in detail in Examples to be described below.

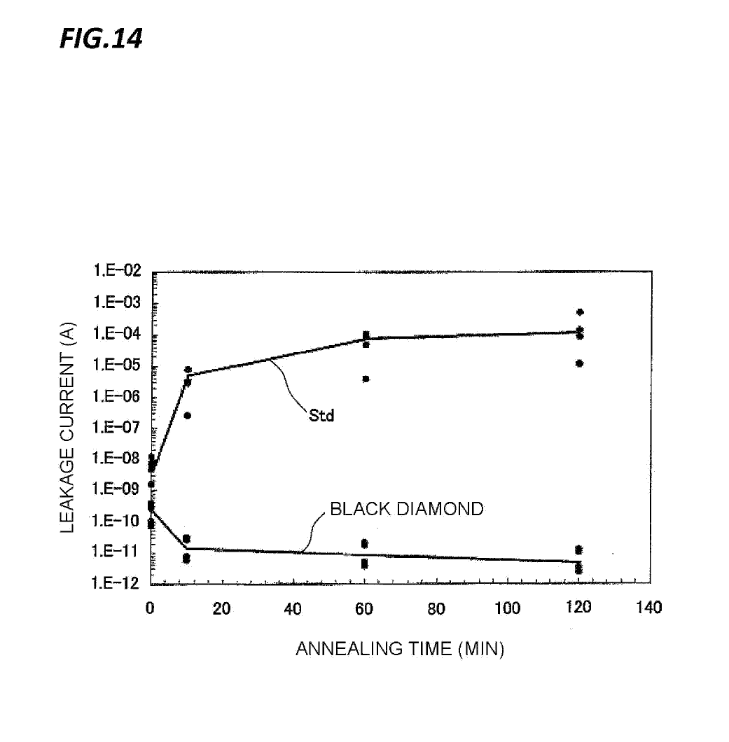

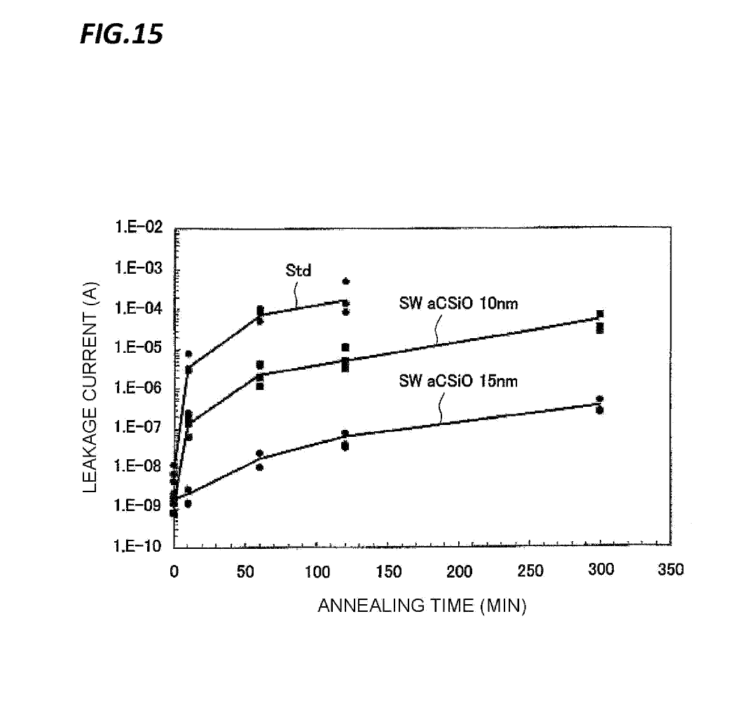

First, the inventors performed an evaluation on a change of a leakage current while performing an annealing process in a case where a CF film was used as an interlayer insulating film, and in a case where BD (Black Diamond) was used as an interlayer insulating film. FIG. 14 is a graph illustrating a change of a leakage current (at a voltage load of 20V) when the annealing process was performed under a condition of 350° C. in which the change of the leakage current was measured on a semiconductor device manufactured by using a CF film (“Std” in the graph) as an interlayer insulating film, and a semiconductor device manufactured by using BD (“Black Diamond” in the graph) as an interlayer insulating film. In both cases, Ti (titanium) was used as a barrier metal film. In FIG. 14, the horizontal axis represents an annealing time (min), and the vertical axis represents a leakage current.

As illustrated in FIG. 14, it was found that in the semiconductor devices manufactured by using the CF film as the interlayer insulating film, the leakage current increased in proportion to the length of annealing processing time. Meanwhile, it was found that in the semiconductor devices manufactured by using the BD as the interlayer insulating film, stabilization of a crystal structure by the annealing process was facilitated with elapse of annealing processing time, thereby decreasing the leakage current. That is, it was found that, when an interlayer insulating film was a CF film in a semiconductor device, a leakage current increased when the annealing process was performed. It was estimated that this was resulted from the following reason: fluorine was diffused to Ti used as a barrier metal film from a CF film which is an interlayer insulating film and TiF₄ was generated, thereby reducing the Ti density within the barrier metal film.

Subsequently, an evaluation was made on a change of a leakage current in a case where a fluorine barrier film which is a characteristic of the present disclosure is formed between an interlayer insulating film which is a CF film and a barrier metal film. FIG. 15 is a graph illustrating a change of a leakage current (at a voltage load of 20V) when the annealing process was performed under a condition of 350° C., in which the change of the leakage current was measured on a semiconductor device manufactured without forming a fluorine barrier film (“Std” in the drawing), a semiconductor device manufactured by forming a fluorine barrier film (aCSiO) of 10 nm thickness (SW aCSiO 10 nm in the drawing) between an interlayer insulating film and a barrier metal film, and a semiconductor device manufactured by forming a fluorine barrier film (aCSiO) of 15 nm thickness (SW aCSiO 15 nm in the drawing) between an interlayer insulating film and a barrier metal film. In each case, as a barrier metal film, Ti was used. In FIG. 15, the horizontal axis represents an annealing time (min), and the vertical axis represents a leakage current.

As illustrated in FIG. 15, it was found that, in connection with an annealing process (heat loading process), when a fluorine barrier film was formed during the manufacturing of a semiconductor device, an increase of a leakage current was suppressed as compared to a case where the fluorine barrier film was not formed. Further, it was found that as the thickness of the fluorine barrier film was increased, the increase of the leakage current was further suppressed.

From the above described Examples, it was found that, when a fluorine barrier film is formed between an interlayer insulating film (a CF film) and a barrier metal film during the manufacturing of a semiconductor device using the CF film, it is possible to suppress fluorine from being diffused from the CF film to the barrier metal film unlike a conventional semiconductor device in which fluorine is diffused. Also, it was found that, when a heat treatment process such as, for example, an annealing process is performed on a semiconductor device, an increase of leakage current is suppressed, and thus, for example, a device defect may be avoided.

### INDUSTRIAL APPLICABILITY

The present disclosure is applicable to a semiconductor device and a method for manufacturing the semiconductor device.

Description of Symbols

| | |
|---|---|
| 1: Substrate main body | 2: Interlayer insulating film |
| 4: Wiring groove | 5: Fluorine barrier film |
| 6: Barrier metal (BM) film | 10: Cu conductive layer |
| 15: Cu wiring | 17: Sealing film |
| 18: Cu wiring structure | 18a: Cu wiring structure |
| | (first layer) |
| 18b: Cu wiring structure (second layer) | 30: Interlayer insulating film |
| 32: Wiring groove | 32a: Trench groove |
| 32b: Via hole | 35: Fluorine barrier film |
| 36: Barrier metal (BM) film | 40: Cu conductive layer |
| 45: Cu wiring | 48: Cu wiring structure |
| W: Substrate | |

1. A semiconductor device having a damascene wiring structure, the semiconductor device comprising:
an interlayer insulating film including a fluorine-added carbon film; and
a copper wiring filled in the interlayer insulating film,
wherein between the interlayer insulating film and the copper wiring, a barrier metal layer and a fluorine barrier film are formed close to the copper wiring and the interlayer insulating film, respectively,
the fluorine barrier film is an aCSiO (amorphous carbon silicon oxide) film, an aCSiON (amorphous carbon silicon oxide nitride) film, or a SiCN (silicon carbon nitride) film, and
oxygen (O) or nitrogen (N) is introduced in the second half of the film formation of the fluorine barrier film.

2. (canceled)

3. The semiconductor device of claim 1, wherein the fluorine barrier film has a thickness of 5 nm or more.

4. A method for manufacturing a semiconductor device having a damascene wiring structure, the method comprising:
forming an interlayer insulating film including a fluorine-added carbon film,
forming a wiring groove on the interlayer insulating film,
forming a fluorine barrier film in the wiring groove,
forming a barrier metal layer on a surface of the fluorine barrier film, and
forming a copper wiring in the wiring groove after the fluorine barrier film and the barrier metal layer are formed,
wherein the fluorine barrier film is an aCSiO (amorphous carbon silicon oxide) film, an aCSiON (amorphous carbon silicon oxide nitride) film, or a SiCN (silicon carbon nitride) film, and
oxygen (O) or nitrogen (N) is introduced in the second half of the film formation at the forming a fluorine barrier film.

5. (canceled)

6. The method of claim 4, wherein the fluorine barrier film has a thickness of 5 nm or more.
